(19) United States
(12) Patent Application Publication
(10) Pub. No.: US 2021/0265413 A1
(43) Pub. Date: Aug. 26, 2021

(54) OPTICAL DEVICE, SPECTRAL SENSOR MODULE, IMAGING MODULE, AND METHOD FOR MANUFACTURING OPTICAL DEVICE

(71) Applicant: MICRO MODULE TECHNOLOGY CO., LTD., Kanagawa (JP)

(72) Inventor: Fumikazu HARAZONO, Kanagawa (JP)

(21) Appl. No.: 17/314,789

(22) Filed: May 7, 2021

Related U.S. Application Data
(63) Continuation of application No. PCT/JP2019/043508, filed on Nov. 6, 2019.

(30) Foreign Application Priority Data
Nov. 16, 2018 (JP) 2018-216034

(51) Int. Cl. H01L 27/146; H01L 23/528; H01L 23/522; H01L 31/0232

(52) U.S. Cl. CPC H01L 27/14636; H01L 31/0232; H01L 23/5226; H01L 23/528

(57) ABSTRACT

Penetration of unnecessary light in an optical path through which light from an object passes can be prevented. Optical components on which the light from the object is incident, a selective transmission member that transmits a light at a predetermined wavelength among lights that have transmitted through the optical component, and a light receiving unit that receives the light that has transmitted through the selective transmission member are held inside an opaque three-dimensional wiring substrate that energizes the light receiving unit.

### CROSS-REFERENCE TO RELATED APPLICATIONS

This application is a continuation application of International Patent Application No. PCT/JP2019/043508 filed on Nov. 6, 2019, which claims priority to Japanese Patent Application No. 2018-216034 filed on Nov. 16, 2018, the entire contents of which are incorporated by reference.

### TECHNICAL FIELD

The present invention relates to an optical device, a spectral sensor module, an imaging module, and a method for manufacturing the optical device.

### BACKGROUND ART

Patent Document 1 discloses an optical pickup device that includes a housing made of a transparent resin, a collimator lens portion, a rising mirror portion, and a hologram laser attachment portion, which are integrally molded.

### CITATION LIST

### Patent Literature

Patent Document 1: JP 2005-141853 A

However, since the housing of the optical pickup device disclosed in Patent Document 1 is transparent, unnecessary light (light other than light from an object) penetrates into an optical path inside the optical pickup device, possibly resulting in mixture of the light from the object with the unnecessary light.

Furthermore, despite being opaque, in a case where a plurality of members are joined to form a single housing, unnecessary light (in particular, infrared light) penetrates into the inside of the housing from joining portions of the plurality of members, possibly resulting in mixture of the light from the object with the unnecessary light.

### SUMMARY OF INVENTION

One or more embodiments of of the present invention are directed to an optical device, a spectral sensor module, an imaging module, and a method for manufacturing the optical device that allow preventing unnecessary light from passing through an optical path through which light from an object passes.

An optical device according to one or more embodiments of the present invention includes an optical component, a selective transmission member, a light receiving unit (light receiver), and an opaque three-dimensional wiring substrate. Light from an object is incident on the optical component. The selective transmission member transmits a light at a predetermined wavelength among lights that have transmitted through the optical component. The light receiving unit receives the light that has transmitted through the selective transmission member. The opaque three-dimensional wiring substrate energizes the light receiving unit. The three-dimensional wiring substrate has a through-hole. The optical component, the selective transmission member, and the light receiving unit are held inside the through-hole.

According to one or more embodiments of the present invention, since the optical component, the selective transmission member, and the light receiving unit are held inside the three-dimensional wiring substrate without a joint, unnecessary light does not penetrate from outside the three-dimensional wiring substrate. This allows increasing measurement accuracy of the optical device and accuracy of a captured image.

The through-hole may include a first abutment surface substantially orthogonal to an axis of the through-hole. The first abutment surface may face a first surface of the three-dimensional wiring substrate. The optical component may be provided inside the through-hole by bringing an emission surface from which the light is emitted into abutment with the first abutment surface. As a result, a positional relationship between the optical component and the three-dimensional wiring substrate can be easily determined, and assembly is easy. Furthermore, the positional relationship between an optical component and a housing is less likely to be changed over time, and the highly reliable optical device can be achieved over a long period of time.

The through-hole may include a second abutment surface substantially orthogonal to the axis of the through-hole. The second abutment surface may face a second surface different from the first surface of the three-dimensional wiring substrate. The light receiving unit may be provided inside the through-hole by bringing an incident surface on which light is incident into abutment with the second abutment surface. As a result, a positional relationship between the light receiving unit and the three-dimensional wiring substrate can be easily determined, and assembly is easy. Additionally, electricity can be supplied to the light-receiving unit by only bringing the light receiving unit into abutment with the three-dimensional wiring substrate.

The through-hole may have a second abutment surface substantially orthogonal to the axis of the through-hole. The second abutment surface may face a second surface different from the first surface of the three-dimensional wiring substrate. The selective transmission member may include a glass substrate and a wiring pattern provided on the glass substrate. The selective transmission member may be provided inside the through-hole by bringing the glass substrate into abutment with the second abutment surface. The light receiving unit may be provided on a surface on a side opposite to a surface in contact with the second abutment surface of the selective transmission member. The wiring pattern may abut on the three-dimensional wiring substrate and the light receiving unit. Thus using the selective transmission member as an interposer allows using various sensor devices as the light receiving unit.

The light receiving unit may include a protrusion provided on an electrode of the light-receiving unit. The protrusion may abut on the wiring pattern. As a result, an interval between the selective transmission member and the light receiving unit can be maintained constant.

A spacer provided inside the through-hole is further provided. The optical component may include at least a first optical component and a second optical component. The first optical component may abut on the first abutment surface. The second optical component may abut on the spacer. The spacer may have a distal end located in a vicinity of the first optical component. Accordingly, a distance between the first and second optical components can be determined by the spacer. In addition, regardless of a size of the second optical component, the second optical component can be held inside the through-hole. Furthermore, the use of the spacer facilitates assembly, and positioning of the first optical component and the second optical component is also easy.

The selective transmission member may include a diffraction grating that transmits a light at a wavelength in a predetermined range among lights incident on the selective transmission member. Since the entire selective transmission member causes the light at a wavelength in a predetermined range to pass through, this case is effective to disperse, for example, infrared light and ultraviolet light.

The light-receiving unit or the selective transmission member may include a diffraction grating that causes the light receiving unit to receive light at a wavelength different depending on each pixel. The selective transmission member may include a plasmon filter that causes the light receiving unit to receive a light at a wavelength different depending on each pixel. As a result, the light at the wavelength different depending on each pixel can be received in the light-receiving unit.

A spectral sensor module according to another aspect of the present invention is a spectral sensor module that includes the optical device according to any one of the above-described optical devices and a diffuser as the optical component. The light receiving unit is a spectral sensor configured to measure intensity of the light that has transmitted through the selective transmission member for each wavelength. According to this configuration, the spectral sensor module that efficiently guides the light from the object to the light receiving unit can be provided.

An imaging module according to yet another aspect of the present invention is an imaging module that includes the optical device according to any one of the above-described optical devices and a lens unit. The lens unit includes a plurality of lenses as the optical component. The light receiving unit is an imaging element. According to this configuration, an imaging module that efficiently guides the light from the object to the light receiving unit can be provided.

A method for manufacturing an optical device according to the present invention includes: (a) placing a three-dimensional wiring substrate including a first abutment surface and a second abutment surface substantially orthogonal to an axis of a through-hole opening to a first surface and a second surface with the second surface upward; (b) inserting a selective transmission member that transmits a light at a predetermined wavelength into the through-hole and bringing the selective transmission member into abutment with the second abutment surface to provide the selective transmission member inside the through-hole; (c) inserting a light receiving unit that receives the light that has transmitted through the selective transmission member into the through-hole; (d) placing the three-dimensional wiring substrate with the first surface upward; (e) inserting an optical component into the through-hole and bringing the optical component into abutment with the first abutment surface to provide the optical component inside the through-hole; and (f) inserting an upper end member into the through-hole, bringing the upper end member into abutment with the optical component, and sealing an adhesive between the upper end member and the through-hole to provide the upper end member inside the through-hole. As a result, the optical device in which the unnecessary light does not penetrate from outside the three-dimensional wiring substrate can be easily assembled. Additionally, only inserting the respective members into the through-hole allows easily determining mutual distances.

The optical component may include at least a first optical component and a second optical component. The step (e) may include: (e1) inserting the first optical component into the through-hole and bringing the first optical component into abutment with the first abutment surface to provide the first optical component inside the through-hole; (e2) inserting a spacer into the through-hole and bringing the spacer into abutment with the first optical component to provide the spacer inside the through-hole; and (e3) inserting the second optical component into the through-hole and bringing the second optical component into abutment with the spacer to provide the second optical component inside the through-hole. In this way, a distance between the first optical component and the second optical component can be defined by the spacer. In addition, regardless of the size of the second optical component, by only inserting the components into the through-hole in order, the optical device can be assembled.

The three-dimensional wiring substrate may include a third abutment surface substantially orthogonal to the axis of the through-hole. In step (c), the light receiving unit may be brought into abutment with the third abutment surface to electrically conduct the light receiving unit and the three-dimensional wiring substrate. In this way, mounting the light receiving unit directly on the three-dimensional wiring substrate allows configuring a simple structure.

The selective transmission member may include a wiring pattern formed on a surface on the selective transmission member. In step (b), the wiring pattern may be electrically conducted with the three-dimensional wiring substrate. In step (c), the light receiving unit may be brought into abutment with the selective transmission member to electrically conduct the wiring pattern and the light receiving unit. In this way, by configuring the selective transmission member as the interposer, various sensor devices can be mounted as the light receiving unit to the selective transmission member.

One or more embodiments of the present invention allows preventing penetration of the unnecessary light in an optical path through which the light from the object passes.

### BRIEF DESCRIPTION OF DRAWINGS

FIG. 1 is a vertical cross-sectional view illustrating an overview of an optical device 1.

FIG. 2 is a flowchart depicting a flow of a manufacturing method of the optical device 1.

FIG. 3 is a vertical cross-sectional view illustrating an overview of an optical device 1A.

FIG. 4 is a vertical cross-sectional view illustrating an overview of an optical device 1B.

FIG. 5 is a flowchart depicting a flow of a manufacturing method of the optical device 1B.

FIG. 6 is a vertical cross-sectional view illustrating an overview of an optical device 1C.

FIG. 7 is a plan view illustrating an overview of a selective transmission member 7B.

FIG. 8 is a diagram schematically illustrating a state in which a light receiving unit 8C is provided on the selective transmission member 7B.

FIG. 9 is a flowchart depicting a flow of a manufacturing method of the optical device 1C.

FIG. 10 is a diagram schematically illustrating a state in which the light receiving unit 8C is provided on a selective transmission member 7C.

### DESCRIPTION OF EMBODIMENTS

Hereinafter, description will be given of embodiments of an optical device according to the present invention with reference to the drawings. The optical device is a device that causes a light receiving unit to receive light from an object. Hereinafter, on an optical path from the object to the light receiving unit, the object side is referred to as above, and the light receiving unit side is referred to as below. Furthermore, the upper side is referred to as a +z-side, the lower side is referred to as a −z-side, and directions substantially orthogonal to the z-direction are referred to as an x-direction and a y-direction.

### First Embodiment

An optical device 1 according to the first embodiment is, for example, a spectral sensor module using a spectral sensor in a light receiving unit.

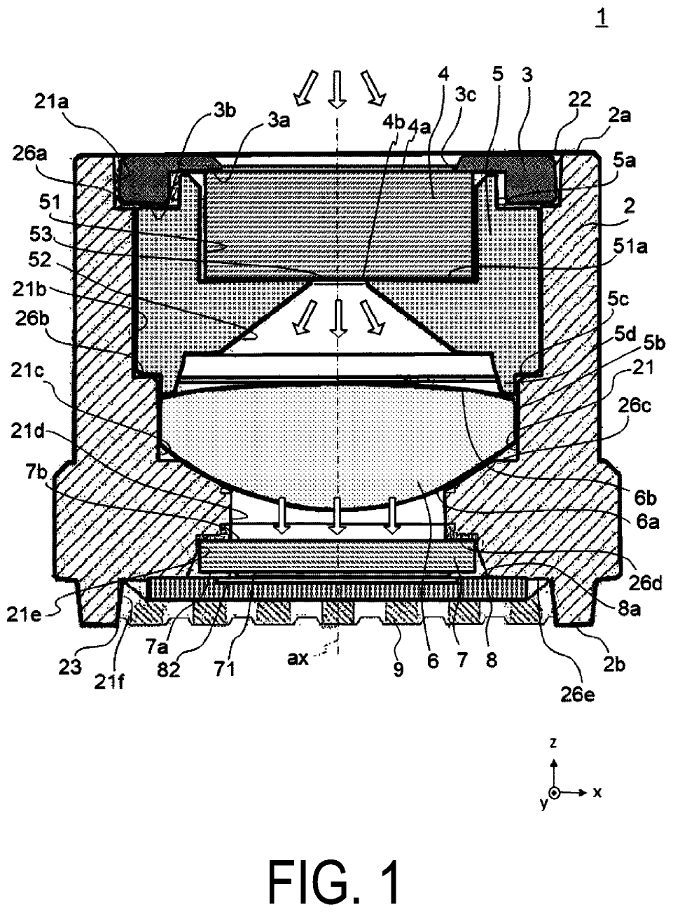

FIG. 1 is a vertical cross-sectional view illustrating an overview of the optical device 1. The optical device 1 mainly includes a three-dimensional wiring substrate 2, an upper end member 3, an optical component 4, a spacer 5, an optical component 6, a selective transmission member 7, and a light receiving unit 8. The object (not illustrated) is provided on an upper side of the optical device 1, and light from the object (see the open arrows in FIG. 1) is incident on the optical device 1 from the upper end member 3 side.

The three-dimensional wiring substrate 2 is a thick flat plate-shaped member, and has a substantially rectangular shape in plan view (as viewed in the z-direction). The shape of the three-dimensional wiring substrate 2 in plan view may be a substantially oblong shape or may be a substantially square shape. The three-dimensional wiring substrate 2 includes a circuit that supplies power to the light receiving unit 8 and measures the light received by the light receiving unit 8. The three-dimensional wiring substrate 2 is configured such that the light receiving unit 8 electrically conducts with the three-dimensional wiring substrate 2 when the three-dimensional wiring substrate 2 is housed in the light receiving unit 8.

A through-hole 21 that penetrates the three-dimensional wiring substrate 2 is provided at substantially the center of the three-dimensional wiring substrate 2 in plan view. A shape of an opening of the through-hole 21 is, for example, a substantially rectangular shape, but may be any shape, such as a substantially square shape and a substantially circular shape. The through-hole 21 penetrates the three-dimensional wiring substrate 2 in the z-direction, and opens to two parallel surfaces of the three-dimensional wiring substrate 2, that is, an upper surface 2a and a bottom surface 2b. The opening on the upper surface 2a side of the through-hole 21 is a first open end 22, and the opening on the bottom surface 2b side of the through-hole 21 is a second open end 23.

Note that while an axis ax of the through-hole 21 is substantially parallel to the z-direction in the present embodiment, the axis ax may be bent by disposing an appropriate optical component inside the through-hole 21 to provide the respective open ends of the through-hole at portions other than the upper surface 2a or the bottom surface 2b. However, the configuration in which the through-hole 21 is open to the upper surface 2a and the bottom surface 2b allows shortening the optical path and thinning the optical device 1.

The upper end member 3, the optical component 4, the optical component 6, the selective transmission member 7, and the light receiving unit 8 are disposed in this order from the above at the inside of the through-hole 21. The upper end member 3 is disposed in the vicinity of the first open end 22. The light receiving unit 8 is disposed in the vicinity of the second open end 23. A configuration that holds respective members at the inside of the three-dimensional wiring substrate 2 will be described later.

The upper end member 3 is an annular member. At least a part of a region 3b on the outer peripheral side in a bottom surface of the upper end member 3 protrudes downward of a region 3a on the inner peripheral side. The region 3a abuts on an incident surface 4a of the optical component 4, and the region 3b abuts on an upper surface 5a of the spacer 5. The upper end member 3 is fixed to the three-dimensional wiring substrate 2 with an adhesive member (not illustrated).

A through-hole 3c is provided at substantially the center of the upper end member 3, and light is incident on the optical component 4 via the through-hole 3c.

The optical component 4 is an optical component on which the light from the object is incident. In the present embodiment, the optical component 4 is a diffuser (a light diffusion plate). The optical component 4 equalizes wavelengths contained in the light from the object and emits them to the optical component 6.

The spacer 5 is disposed between the optical component 4 and the optical component 6. An optical component housing portion 51 that houses the optical component 4 is formed on the upper surface 5a side of the spacer 5. The optical component housing portion 51 has a recessed shape corresponding to the outer periphery of the optical component 4, and is, for example, a substantially cylindrical recessed portion.

A light-guiding unit 52 having an inner diameter increasing toward the downstream of the optical path is formed on a lower surface 5c side of the spacer 5. The light-guiding unit 52 may be a substantially frusto-conical-shaped recessed portion or may be a substantially truncated square pyramid-shaped recessed portion.

The optical component housing portion 51 communicates with the light-guiding unit 52 with a through-hole 53. The light emitted from the optical component 4 housed in the optical component housing portion 51 is guided through the through-hole 53 and the light-guiding unit 52 to the lower side of the spacer 5, and is incident on the optical component 6.

A bottom surface 51a of the optical component housing portion 51 abuts on an emission surface 4b of the optical component 4. Further, a distal end surface 5b abuts on an incident surface 6b of the optical component 6. In other words, the spacer 5 defines an interval between the optical component 4 and the optical component 6.

The optical component 6 is an optical component on which the light emitted from the optical component 4 is incident. In the present embodiment, the optical component 6 is a collimating lens. The optical component 6 collimates the incident light into parallel light.

The selective transmission member 7 is, for example, an optical filter, and is a member that transmits a light at a predetermined wavelength among the lights emitted from the optical component 6. The selective transmission member 7 includes a selective transmission unit 71, such as a diffraction grating or a plasmon filter.

In the selective transmission member 7, a diffraction grating that transmits a light (for example, infrared light or ultraviolet light) at a wavelength in a predetermined range among the lights incident on the selective transmission member 7 may be formed. Further, a color filter (for example, a diffraction grating or a plasmon filter) that causes the light receiving unit 8 to receive light at a wavelength different depending on each pixel may be formed in the selective transmission member 7.

The selective transmission unit 71 is provided on a surface 7a on the light receiving unit 8 side of the selective transmission member 7. When the selective transmission unit 71 is separated from a sensor unit 82, lights diffuse to interfere with the adjacent pixels. Accordingly, the selective transmission unit 71 is provided on the surface 7a such that the selective transmission unit 71 and the sensor unit 82 become as close as possible. An antireflection film is provided on a surface 7b on a side opposite to the surface 7a.

The light receiving unit 8 is a member that receives the light that has transmitted through the selective transmission member 7. The sensor unit 82 (for example, a photodiode) on which the light is incident is provided on an incident surface 8a that abuts on the three-dimensional wiring substrate 2 of the light receiving unit 8. In addition, an electrode (not illustrated) is exposed to the incident surface 8a, and power is supplied by bringing the electrode into abutment with the three-dimensional wiring substrate 2.

In a case where the selective transmission member 7 entirely causes light at a wavelength in a predetermined range to pass through, the sensor unit 82 receives the light within the predetermined range at all the pixels. In addition, when the selective transmission unit 71 is a color filter, the sensor unit 82 receives light at a wavelength different depending on each pixel.

Next, a configuration in which respective members are held inside the through-hole 21 will be described. The through-hole 21 includes a first hole portion 21a, a second hole portion 21b, a third hole portion 21c, a fourth hole portion 21d, a fifth hole portion 21e, and a sixth hole portion 21f, which are provided in this order from the +z-side. The inner diameter of the first hole portion 21a is larger than the inner diameter of the second hole portion 21b, the inner diameter of the second hole portion 21b is larger than the inner diameter of the third hole portion 21c, and the inner diameter of the third hole portion 21c is larger than the inner diameter of the fourth hole portion 21d. The inner diameter of the sixth hole portion 21f is larger than the inner diameter of the fifth hole portion 21e, and the inner diameter of the fifth hole portion 21e is larger than the inner diameter of the fourth hole portion 21d.

An abutment surface 26a, which is substantially orthogonal to the axis ax of the through-hole 21, is formed between the first hole portion 21a and the second hole portion 21b so as to face the direction of the upper surface 2a. By bringing the region 3b of the upper end member 3 into abutment with the abutment surface 26a, the upper end member 3 is provided inside the first hole portion 21a. The first hole portion 21a has a shape corresponding to an outer peripheral shape of the upper end member 3, and a size of the outer peripheral surface of the upper end member 3 is substantially the same as the size of the inner peripheral surface of the first hole portion 21a.

An abutment surface 26b, which is substantially orthogonal to the axis ax of the through-hole 21, is formed between the second hole portion 21b and the third hole portion 21c so as to face the direction of the upper surface 2a. By bringing the lower surface 5c of the spacer 5 into abutment with the abutment surface 26b, the spacer 5 is provided inside the second hole portion 21b. The second hole portion 21b has a shape corresponding to an outer peripheral shape of the spacer 5, and a size of the outer peripheral surface of the spacer 5 is substantially the same as the size of the inner peripheral surface of the second hole portion 21b.

Furthermore, by providing the optical component 4 in the optical component housing portion 51, the optical component 4 is provided inside the first hole portion 21a and the second hole portion 21b.

An abutment surface 26c, which is substantially orthogonal to the axis ax of the through-hole 21, is formed between the third hole portion 21c and the fourth hole portion 21d so as to face the direction of the upper surface 2a. By bringing an emission surface 6a of the optical component 6 into abutment with the abutment surface 26c, the optical component 6 is provided inside the third hole portion 21c. The third hole portion 21c has a shape corresponding to an outer peripheral shape of the optical component 6, and a size of the outer peripheral surface of the optical component 6 is substantially the same as the size of the inner peripheral surface of the third hole portion 21c.

In addition, a protrusion portion 5d provided so as to face downward on the spacer 5, which is provided inside the second hole portion 21b, is inserted into the third hole portion 21c. The distal end surface 5b of the protrusion portion 5d is located in the vicinity of the incident surface 6b of the optical component 6. Note that the distal end surface 5b and the incident surface 6b may or need not to abut on each other.

An abutment surface 26d, which is substantially orthogonal to the axis ax of the through-hole 21, is formed between the fourth hole portion 21d and the fifth hole portion 21e so as to face the direction of the bottom surface 2b. By bringing the surface 7a of the selective transmission member 7 into abutment with the abutment surface 26d, the selective transmission member 7 is provided inside the fifth hole portion 21e. The fifth hole portion 21e has a shape corresponding to an outer peripheral shape of the selective transmission member 7, and a size of the outer peripheral surface of the selective transmission member 7 is substantially the same as the size of the inner peripheral surface of the fifth hole portion 21e.

An abutment surface 26e, which is substantially orthogonal to the axis ax of the through-hole 21, is formed between the fifth hole portion 21e and the sixth hole portion 21f so as to face the direction of the bottom surface 2b. By bringing the incident surface 8a of the light receiving unit 8 into abutment with the abutment surface 26e, the light receiving unit 8 is provided inside the sixth hole portion 21f. A heat sink 9 is provided on the lower side of the light receiving unit 8. The sixth hole portion 21f has a shape corresponding to an outer peripheral shape of the light receiving unit 8, and a size of the outer peripheral surface of the light receiving unit 8 is substantially the same as the size of the inner peripheral surface of the sixth hole portion 21f.

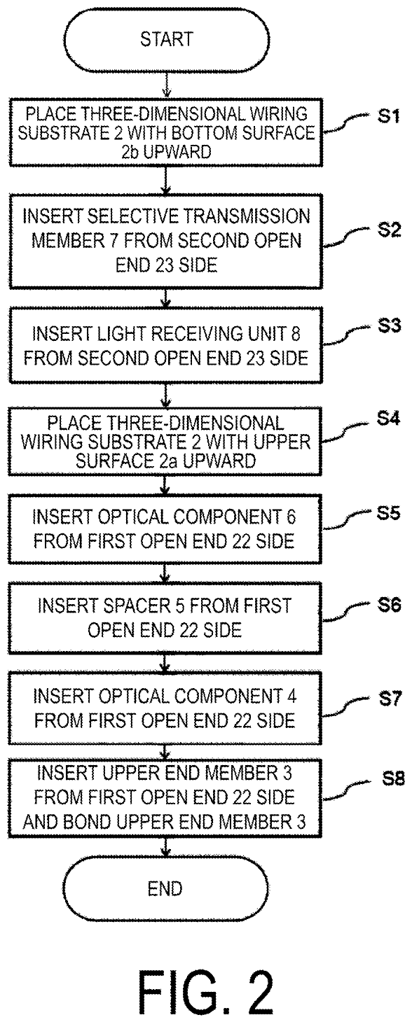

FIG. 2 is a flowchart depicting a flow of a manufacturing method of the optical device 1. First, the three-dimensional wiring substrate 2 is placed with the bottom surface 2b upward (step SD. Next, the selective transmission member 7 is inserted into the through-hole 21 from the second open end 23 side, and the selective transmission member 7 is brought into abutment with the abutment surface 26d (step S2). As a result, the selective transmission member 7 is provided inside the fifth hole portion 21e.

Next, the light receiving unit 8 is inserted into the through-hole 21 from the second open end 23 side, and the light receiving unit 8 is brought into abutment with the abutment surface 26d (step S3). As a result, the light receiving unit 8 is provided inside the sixth hole portion 21f. Further, in step S3, the light receiving unit 8 and the three-dimensional wiring substrate 2 are brought into abutment to electrically conduct the light receiving unit 8 and the three-dimensional wiring substrate 2.

Thereafter, the top and bottom of the three-dimensional wiring substrate 2 are turned over, and the three-dimensional wiring substrate 2 is placed with the upper surface 2a upward (step S4). Next, the optical component 6 is inserted into the through-hole 21 from the first open end 22 side, and the optical component 6 is brought into abutment with the abutment surface 26c (step S5). As a result, the optical component 6 is provided inside the third hole portion 21c.

Next, the spacer 5 is inserted into the through-hole 21 from the first open end 22 side, and the spacer 5 is brought into abutment with the abutment surface 26c (step S6). As a result, the spacer 5 is provided inside the second hole portion 21b. In addition, by positioning the distal end surface 5b of the spacer 5 in the vicinity of the incident surface 6b of the optical component 6, the optical component 6 is positioned in the z-direction inside the through-hole 21.

Next, the optical component 4 is inserted into the through-hole 21 from the first open end 22 side, and the optical component 4 is housed in the optical component housing portion 51 of the spacer 5 (step S7). Next, the upper end member 3 is inserted into the through-hole 21 from the first open end 22 side, the upper end member 3 is brought into abutment with the abutment surface 26a, and an adhesive is sealed between the upper end member 3 and the through-hole 21 to fix the upper end member 3 to the inside of the through-hole 21 (step S8).

In step S8, the adhesive may be applied to the outer peripheral surface of the upper end member 3 and the upper end member 3 may be inserted into the through-hole 21 to bond the upper end member 3 and the three-dimensional wiring substrate 2 together. Alternatively, after the adhesive is applied to the inner peripheral surface of the first hole portion 21a, the upper end member 3 may be inserted into the through-hole 21 to bond the upper end member 3 and the three-dimensional wiring substrate 2 together. Note that an aspect of the adhesive is optional. For example, a liquid or viscous adhesive may be applied, or a sheet-like adhesive may be pasted. In addition to the bonding between the upper end member 3 and the three-dimensional wiring substrate 2, the upper end member 3 and the spacer 5 may be bonded.

As a result, the upper end member 3 and the optical component 4 are provided inside the first hole portion 21a and the second hole portion 21b. In addition, the upper end member 3 abuts on the incident surface 4a of the optical component 4 and the upper surface 5a of the spacer 5, and the optical component 4 and the spacer 5 are positioned in the z-direction inside the through-hole 21.

Note that steps S4 to S8 may be performed before steps S1 to S3.

According to the present embodiment, the upper end member 3, the optical component 4, the spacer 5, the optical component 6, the selective transmission member 7, and the light receiving unit 8 are inserted into and housed in the through-hole 21 of the three-dimensional wiring substrate 2. Accordingly, configuring the three-dimensional wiring substrate 2 as an opaque three-dimensional wiring substrate allows preventing unnecessary light from penetrating the optical path through which the light from the object passes (the optical path from the upper end member 3 to the light-receiving portion 8). As a result, the light receiving unit 8 can receive only the light from the object, and measurement accuracy of the optical device 1 can be increased.

In particular, according to the present embodiment, configuring the three-dimensional wiring substrate 2 to be the opaque three-dimensional wiring substrate eliminates the need for providing, for example, a wiring substrate in the three-dimensional wiring substrate 2. Thus, the three-dimensional wiring substrate 2 can be configured as a single component, thereby ensuring eliminating a joining portion. This allows avoiding the unnecessary light (especially infrared light) to penetrate the inside of the housing from joining portions of a plurality of members.

In addition, according to the present embodiment, since the upper end member 3, the optical component 4, the spacer 5, the optical component 6, the selective transmission member 7, and the light receiving unit 8 are provided inside the through-hole 21 with reference to the abutment surfaces 26a to 26e inside the through-hole 21, simply inserting the respective members into the through-hole 21 allows easily determining the positions of the respective members, thus facilitating the assembly. Furthermore, even when time elapses, the positional relationship between the respective members is less likely to be changed, and the highly reliable optical device 1 can be achieved over a long period of time. Furthermore, the use of the spacer 5 allows assembling the optical device 1 by only inserting the respective members into the through-hole in order, regardless of the size of the optical component 4.

Note that in the present embodiment, the spacer 5 is provided between the optical component 4 and the optical component 6, but the spacer 5 is not essential. For example, when the size of the optical component 4 in plan view is configured to be larger than the size of the optical component 6 in plan view and the optical component 4 is directly placed on the abutment surface 26a, the spacer 5 is unnecessary.

### Modification of First Embodiment

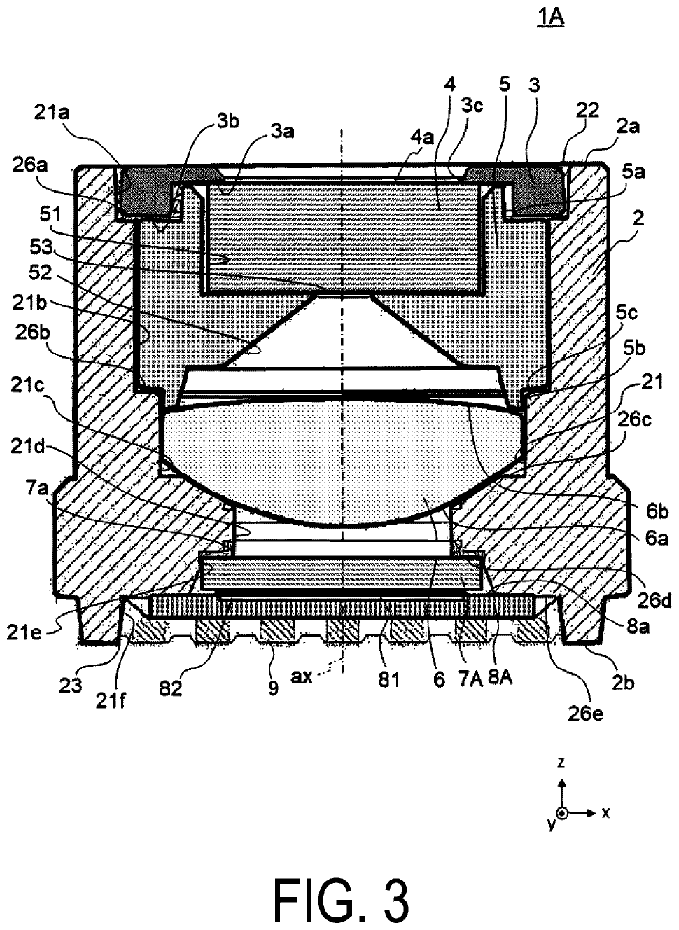

In the present embodiment, the selective transmission unit 71, such as the diffraction grating and the plasmon filter, is provided in the selective transmission member 7, but the selective transmission unit may be provided on the incident surface 8a of the light receiving unit 8. FIG. 3 is a vertical cross-sectional view of an optical device 1A according to the modification of the first embodiment.

The optical device 1A mainly includes the three-dimensional wiring substrate 2, the upper end member 3, the optical component 4, the spacer 5, the optical component 6, a selective transmission member 7A, and a light receiving unit 8A.

The selective transmission member 7A is an optical filter and narrows a wavelength range of the light incident on the light receiving unit 8A. The optical filter is, for example, a diffraction grating.

A diffraction grating 81 that disperses the light incident on the light receiving unit 8A and emits the light is formed as the selective transmission unit on the incident surface 8a on the upper side of the light receiving unit 8A. The diffraction grating 81 is nanoimprinted on the light receiving unit 8A. This configuration reduces the number of components compared to the case where the diffraction grating is provided separately from the light receiving unit 8A, and thus the optical device 1 can be thinned. The light receiving unit 8A is similar to the light receiving unit 8 except for the diffraction grating 81.

### Second Embodiment

An optical device 1B according to the second embodiment is, for example, an imaging module using an imaging element in a light receiving unit. Hereinafter, the optical device 1B according to the second embodiment will be described mainly in points different from the optical device 1. Note that the same components as those in the optical device 1 are denoted by the same reference numerals, and descriptions thereof will be omitted.

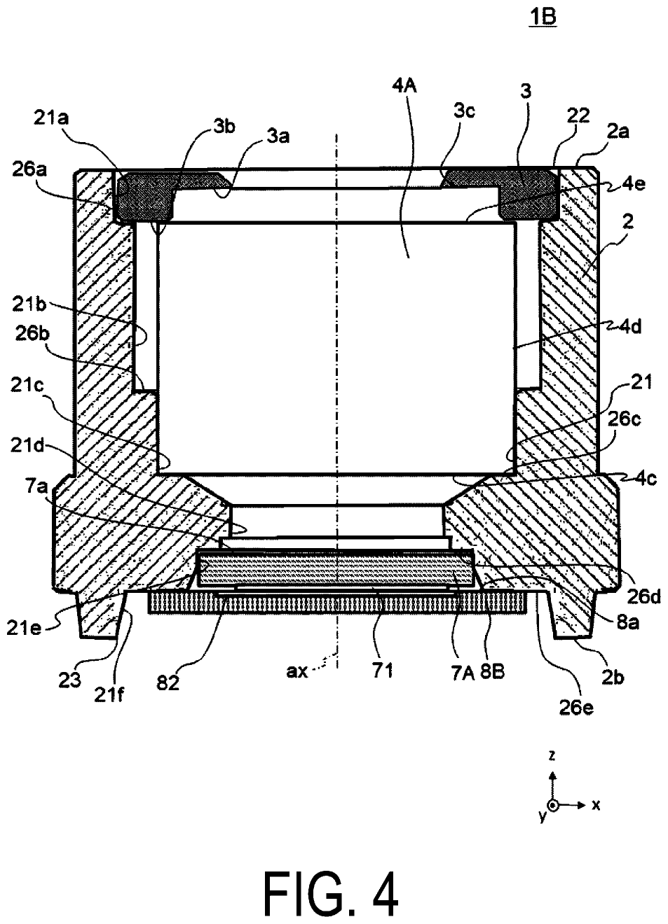

FIG. 4 is a vertical cross-sectional view illustrating an overview of the optical device 1B. The optical device 1B mainly includes the three-dimensional wiring substrate 2, the upper end member 3, an optical component 4A, the selective transmission member 7, and a light receiving unit 8B. The object is provided on an upper side of the optical device 1B, and light from the object is incident on the optical device 1B from the upper end member 3 side.

The optical component 4A has a substantially columnar shape, and is a lens unit provided with a plurality of lenses and diaphragms inside a housing. An external thread (not illustrated) is formed on a side surface 4d of the optical component 4A, and an internal thread (not illustrated) is formed on the inner peripheral surface of the third hole portion 21c. By screwing the external thread and the internal thread and bringing a lower end surface 4c of the optical component 4A into abutment with the abutment surface 26c, the optical component 4A is provided inside the third hole portion 21c. The external thread and the internal thread may be formed by machining, or may be formed during molding of the housing of the three-dimensional wiring substrate 2 and the optical component 4A.

Since the optical component 4A is a component having a length long in the optical axis direction, the spacer 5 is unnecessary. The upper end member 3 abuts on an upper end surface 4e of the optical component 4A. The upper end member 3 is fixed to the three-dimensional wiring substrate 2 with an adhesive member (not illustrated).

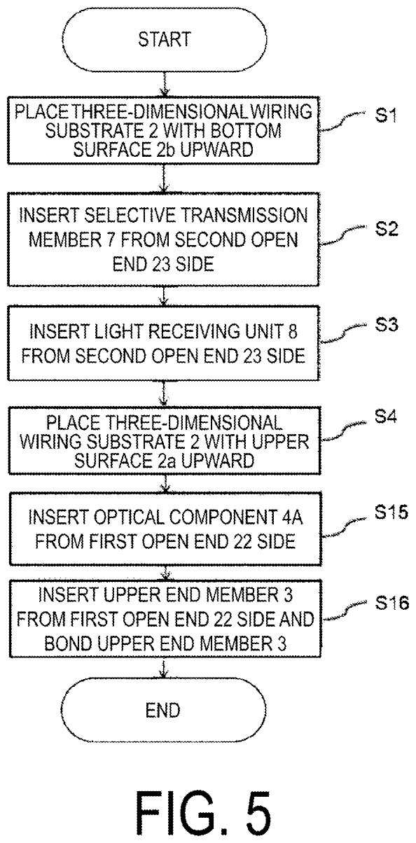

FIG. 5 is a flowchart depicting a flow of a manufacturing method of the optical device 1B. First, the three-dimensional wiring substrate 2 is placed with the bottom surface 2b upward (step SD. Next, the selective transmission member 7 is inserted into the through-hole 21 from the second open end 23 side, and the selective transmission member 7 is brought into abutment with the abutment surface 26d (step S2). Next, the light receiving unit 8B is inserted into the through-hole 21 from the second open end 23 side, and the light receiving unit 8B is brought into abutment with the abutment surface 26d (step S3). The light receiving unit 8B is an imaging element that receives visible light or infrared light and captures an image.

Thereafter, the top and bottom of the three-dimensional wiring substrate 2 are turned over, and the three-dimensional wiring substrate 2 is placed with the upper surface 2a upward (step S4). Next, the optical component 4A is inserted into the through-hole 21 from the first open end 22 side, and the optical component 4A is brought into abutment with the abutment surface 26c (step S15). As a result, the optical component 4A is provided inside the third hole portion 21c.

Next, the upper end member 3 is inserted into the through-hole 21 from the first open end 22 side, the upper end member 3 is brought into abutment with the abutment surface 26a, and an adhesive is sealed between the upper end member 3 and the through-hole 21 to fix the upper end member 3 to the inside of the through-hole 21 (step S16).

As a result, the upper end member 3 and the optical component 4A are provided inside the first hole portion 21a and the second hole portion 21b. Note that steps S4 to S16 may be performed before steps S1 to S3.

According to the present embodiment, an image of the object can be captured using the optical device 1B. For example, it is applicable to a motion camera that senses a movement of an object with infrared light to capture an image of a moving body. Since the three-dimensional wiring substrate 2 is configured as one component and a joining portion is eliminated, unnecessary light (in particular, infrared light) does not penetrate the inside of the three-dimensional wiring substrate 2 from the joining portion. Accordingly, highly accurate images can be captured.

### Third Embodiment

An optical device 1C according to the third embodiment has a configuration in which a circuit is provided on a selective transmission member. Hereinafter, the optical device 1C according to the third embodiment will be described mainly in points different from the optical device 1. Note that the same components as those in the optical device 1 are denoted by the same reference numerals, and descriptions thereof will be omitted. Furthermore, the optical device 1C may be a spectral sensor module using a spectral sensor in a light receiving unit, or may be an imaging module using an imaging element in a light receiving unit.

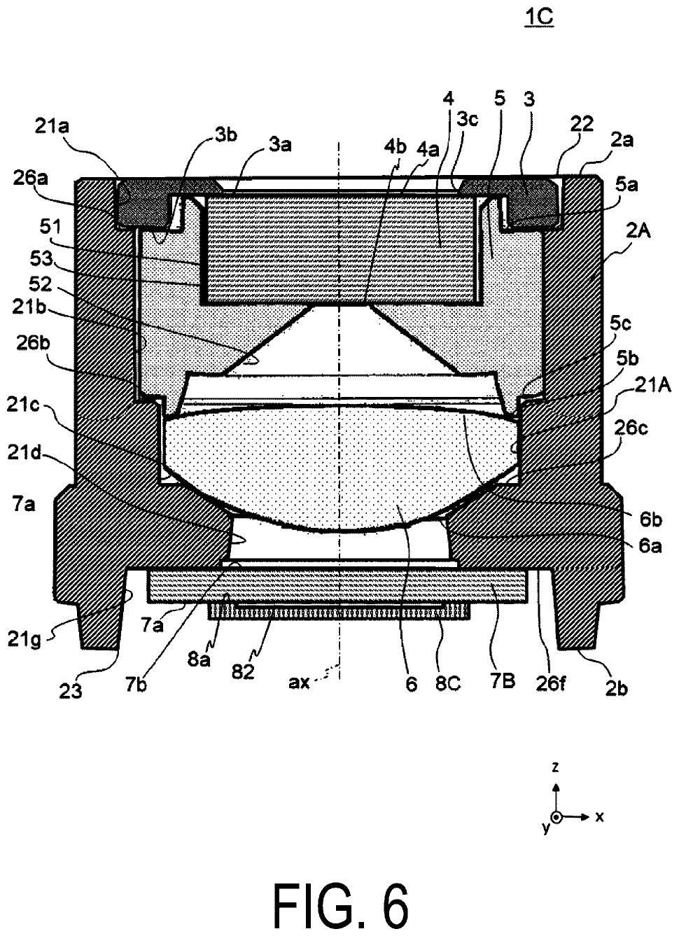

FIG. 6 is a vertical cross-sectional view illustrating an overview of the optical device 1C. The optical device 1C mainly includes a three-dimensional wiring substrate 2A, the upper end member 3, the optical component 4, the spacer 5, the optical component 6, a selective transmission member 7B, and a light receiving unit 8C.

The three-dimensional wiring substrate 2A is a thick flat plate-shaped member, and has a substantially rectangular shape in plan view (as viewed in the z-direction). When the selective transmission member 7B and the light receiving unit 8C are housed in the three-dimensional wiring substrate 2A, the three-dimensional wiring substrate 2A electrically conducts with the light receiving unit 8C via the selective transmission member 7B.

A through-hole 21A that penetrates the three-dimensional wiring substrate 2A is provided at substantially the center of the three-dimensional wiring substrate 2A in plan view. The through-hole 21A includes the first hole portion 21a, the second hole portion 21b, the third hole portion 21c, the fourth hole portion 21d, and a fifth hole portion 21g, which are provided in this order from the +z-side. The inner diameter of the fifth hole portion 21g is larger than the inner diameter of the fourth hole portion 21d.

An abutment surface 26f, which is substantially orthogonal to the axis ax of the through-hole 21, is formed between the fourth hole portion 21d and the fifth hole portion 21g so as to face the direction of the bottom surface 2b. By bringing the surface 7b of the selective transmission member 7B into abutment with the abutment surface 26f, the selective transmission member 7B is provided inside the fifth hole portion 21g.

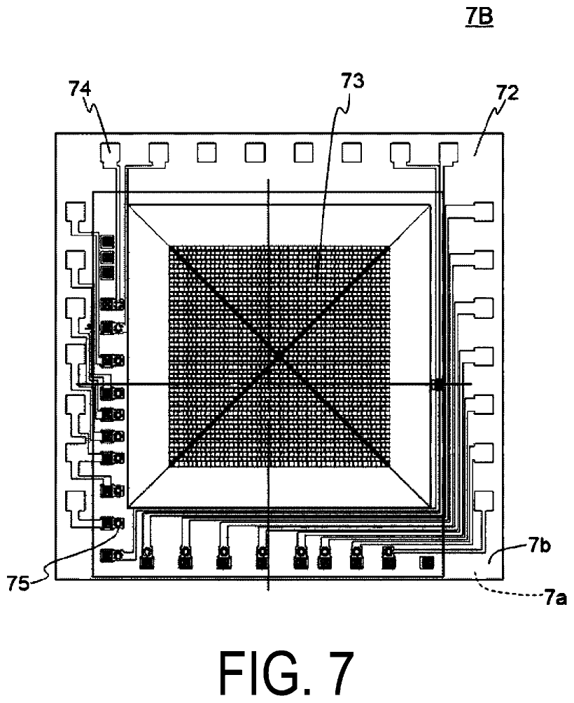

The selective transmission member 7B is a member that transmits a light at a predetermined wavelength among the lights emitted from the optical component 6. FIG. 7 is a plan view illustrating an overview of the selective transmission member 7B.

The selective transmission member 7B includes a glass substrate 72, a selective transmission unit 73, and a wiring pattern 74. The selective transmission unit 73 and the wiring pattern 74 are provided on the glass substrate 72. The selective transmission unit 73 is provided on the surface 7a on the light receiving unit 8B side. The wiring patterns 74 are provided on the surface 7a and the surface 7b. An antireflection film may be provided on the surface 7b.

The selective transmission unit 73 is a color filter that causes the light receiving unit 8B to receive light at a wavelength different depending on each pixel. In the present embodiment, a plasmon filter is used for the selective transmission unit 73. The plasmon filter is a color filter using a surface plasmon principle. In the present embodiment, holes having a diameter of 1 μm or less are periodically formed on the glass substrate 72. By changing a hole diameter and the pitch of the holes, a wavelength passing through the hole is changed. However, the selective transmission unit 73 is not limited to the plasmon filter.

The wiring pattern 74 is a conductive film using Au or Cu. The wiring pattern 74 is mainly provided on the surface 7b, and a part of the wiring pattern 74 is provided on the surface 7a. Furthermore, through-electrodes 75 (TGV, Through-Glass Via) are formed on the glass substrate 72. The through-electrodes 75 electrically conduct the wiring pattern 74 formed on the surface 7a and the wiring pattern 74 formed on the surface 7b.

The description will now return to FIG. 6. When the selective transmission member 7B is provided inside the through-hole 21A, the wiring pattern 74 formed on the surface 7b abuts on the three-dimensional wiring substrate 2A, and the circuit on the three-dimensional wiring substrate 2A electrically conducts with the wiring pattern 74.

The light receiving unit 8C is a member that receives the light that has transmitted through the selective transmission member 7B. The sensor unit 82 on which light is incident is provided on the incident surface 8a that abuts on the selective transmission member 7B of the light receiving unit 8C. The light receiving unit 8C is provided on the selective transmission member 7B so that the incident surface 8a is adjacent to the surface 7a.

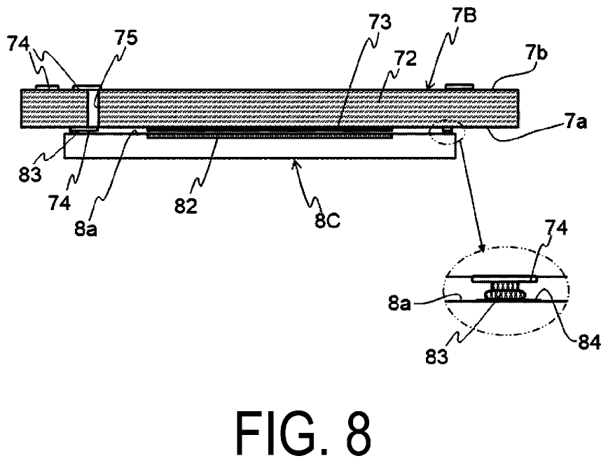

FIG. 8 is a diagram schematically illustrating a state in which the light receiving unit 8C is provided on the selective transmission member 7B. Protrusions (hereinafter referred to as bumps 83) are provided on the incident surface 8a of the light receiving unit 8C. The bump 83 is formed using a conductive body, such as aluminum, gold, and copper.

The bump 83 is formed such that the center portion becomes higher than the other portions. The distal end of the bump 83 (here, the distal end of the center portion higher than the other portions) abuts on the wiring pattern 74. The bumps 83 are provided on electrodes 84 of the light receiving unit 8C. When the bumps 83 abut on the wiring patterns 74, the three-dimensional wiring substrate 2A electrically conducts with the light receiving unit 8C, and power is supplied to the light receiving unit 8C.

In addition, since the bumps 83 are provided on the light receiving unit 8C, an interval between the surface 7a of the selective transmission member 7B and the incident surface 8a of the light receiving unit 8C remains constant. In the present embodiment, the interval between the surface 7a and the incident surface 8a is approximately 10 μm or less.

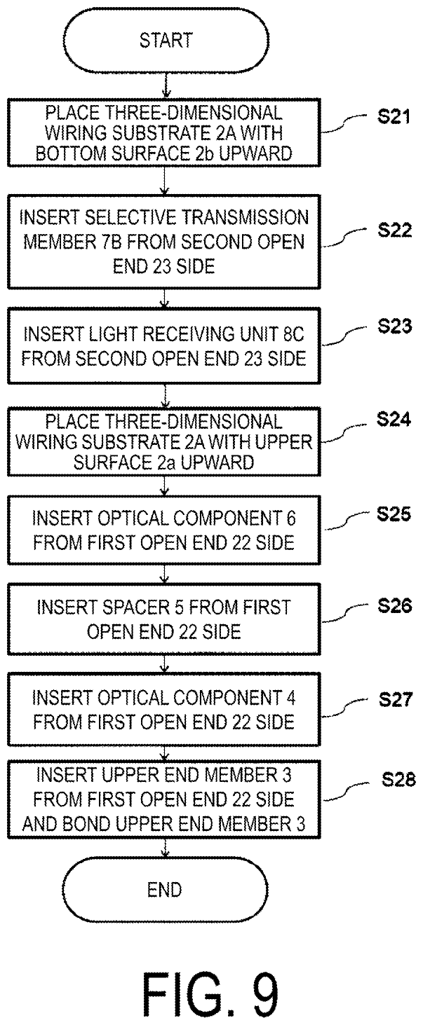

FIG. 9 is a flowchart depicting a flow of a manufacturing method of the optical device 1C. First, the three-dimensional wiring substrate 2A is placed with the bottom surface 2b upward (step S21). Next, the selective transmission member 7B is inserted into the through-hole 21A from the second open end 23 side, and the selective transmission member 7 is brought into abutment with the abutment surface 26f (step S2). As a result, the selective transmission member 7 is provided inside the fifth hole portion 21g.

Next, the light receiving unit 8C is inserted into the through-hole 21 from the second open end 23 side, and the light receiving unit 8C is brought into abutment with the selective transmission member 7B (step S23). As a result, the light receiving unit 8C is provided inside the fifth hole portion 21g. Further, in step S23, the light receiving unit 8C and the selective transmission member 7B are brought into abutment to electrically conduct the light receiving unit 8C and the three-dimensional wiring substrate 2A.

Thereafter, the top and bottom of the three-dimensional wiring substrate 2A are turned over, and the three-dimensional wiring substrate 2A is placed with the upper surface 2a upward (step S24). Next, the optical component 6 is inserted into the through-hole 21A from the first open end 22 side, and the optical component 6 is brought into abutment with the abutment surface 26c (step S25). Next, the spacer 5 is inserted into the through-hole 21A from the first open end 22 side, and the spacer 5 is brought into abutment with the abutment surface 26c (step S26). Next, the optical component 4 is inserted into the through-hole 21A from the first open end 22 side, and the optical component 4 is housed in the optical component housing portion 51 of the spacer 5 (step S27). Next, the upper end member 3 is inserted into the through-hole 21A from the first open end 22 side, and the upper end member 3 is brought into abutment with the abutment surface 26a. An adhesive is sealed between the upper end member 3 and the through-hole 21A to fix the upper end member 3 to the inside of the through-hole 21A (step S28).

The processes of steps S24 to S28 are similar to those of steps S4 to S8. Note that steps S24 to S28 may be performed before steps S21 to S23.

According to the present embodiment, by providing the selective transmission member 7B on the three-dimensional wiring substrate 2A, providing the light receiving unit 8C on the selective transmission member 7B, and using the selective transmission member 7B as an interposer, various sensor devices can be used as the light receiving unit 8C.

For example, in a case where the light receiving unit is directly provided on the three-dimensional wiring substrate, a light receiving unit other than a light receiving unit in which electrodes are provided at positions corresponding to positions of electrodes formed on the three-dimensional wiring substrate cannot be used. In contrast, as in the present embodiment, in the case where the wiring pattern is provided on the selective transmission member and the selective transmission member is the interposer, changing the wiring pattern provided on the selective transmission member allows arranging the positions of the electrodes on the glass substrate again. As such, the application to various sensor devices is possible.

Note that in the present embodiment, by providing the through-electrodes 75 on the glass substrate 72, the wiring pattern 74 formed on the surface 7a and the wiring pattern 74 formed on the surface 7b are electrically conducted. However, a method that electrically conducts the wiring pattern 74 formed on the surface 7a and the wiring pattern 74 formed on the surface 7b is not limited to this.

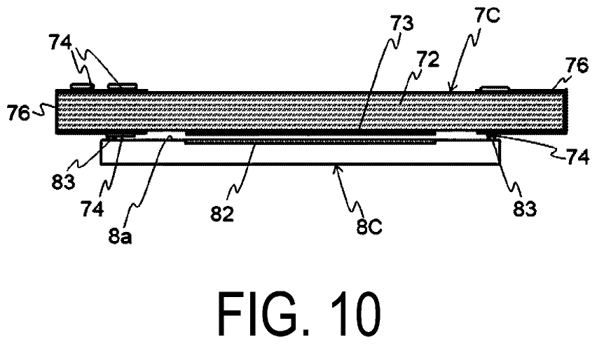

FIG. 10 is a diagram schematically illustrating a state in which the light receiving unit 8C is provided on a selective transmission member 7C according to a modification. A flexible substrate 76 is provided on the selective transmission member 7C along the glass substrate 72. The flexible substrate 76 electrically conducts the wiring pattern 74 formed on the surface 7a and the wiring pattern 74 formed on the surface 7b.

The embodiments of the invention are described above in detail with reference to the drawings. However, specific configurations are not limited to the embodiments and also include changes in design or the like without departing from the gist of the invention.

For example, the technical idea of the present invention is not limited to the spectral sensor or an imaging module, is applicable to other optical devices that collect light from an object and guide the light to a light receiving unit.

Additionally, in the present disclosure, “substantially” is a concept not only including the case of being strictly the same, but also including an error and deformation to the extent that a loss of identity does not occur. For example, a term “substantially parallel” and a term “substantially orthogonal” are not limited to “strictly parallel” and “strictly orthogonal.” In addition, for example, terms such as “parallel,” “orthogonal,” and the like include “substantially parallel,” “substantially orthogonal,” and the like, respectively. To put it differently, those terms are not strictly limited to the parallel state, orthogonal state, and the like, respectively. In addition, the term “vicinity” is used in the present invention to mean a concept where, for example, a place in the vicinity of a certain point A may include the point A or otherwise as long as the place is near the point A.

### REFERENCE SIGNS LIST

1, 1A, 1B, 1C: Optical device
2, 2A: Three-dimensional wiring substrate
2a: Upper surface
2b: Bottom surface
3: Upper end member
3a: Region
3b: Region
3c: Through-hole
4, 4A, 4B: Optical component
4a: Incident surface
4b: Emission surface
4c: Lower end surface
4d: Side surface
4e: Upper end surface
5: Spacer
5a: Upper surface
5b: Distal end surface
5c: Lower surface
5d: Protrusion portion
6: Optical component
6a: Emission surface
6b: Incident surface
7, 7A, 7B, 7C: Selective transmission member
7a, 7b: Surface
8, 8A, 8B, 8C: Light receiving unit
8a: Incident surface
9: Heat sink
21, 21A: Through-hole
21a: First hole portion
21b: Second hole portion
21c: Third hole portion
21d: Fourth hole portion
21e, 21g: Fifth hole portion
21f: Sixth hole portion
22: First open end
23: Second open end
26a, 26b, 26c, 26d, 26e, 26f: Abutment surface
51: Optical component housing portion
51a: bottom surface
52: Light-guiding unit
53: Through-hole
71: Selective transmission unit
72: Glass substrate
73: Selective transmission unit
74: Wiring pattern
75: Through-electrode
76: Flexible substrate
81: Diffraction grating
82: Sensor unit
83: Bump
84: Electrode

1. An optical device comprising:
an optical component on which light from an object is incident;
a selective transmission member that transmits a light at a predetermined wavelength among lights that have transmitted through the optical component;
a light receiver that receives the light that has transmitted through the selective transmission member; and
an opaque three-dimensional wiring substrate that energizes the light receiver, wherein
the three-dimensional wiring substrate has a through-hole, and
the optical component, the selective transmission member, and the light receiver are held inside the through-hole.

2. The optical device according to claim 1, wherein
the through-hole includes a first abutment surface orthogonal to an axis of the through-hole,
the first abutment surface faces a first surface of the three-dimensional wiring substrate,
the optical component has an emission surface from which the light is emitted, and
the emission surface abuts on the first abutment surface.

3. The optical device according to claim 2, wherein
the through-hole includes a second abutment surface orthogonal to the axis of the through-hole,
the second abutment surface faces a second surface different from the first surface of the three-dimensional wiring substrate,
the light receiver has an incident surface on which light is incident, and
the incident surface abuts on the second abutment surface.

4. The optical device according to claim 2, wherein
the through-hole has a second abutment surface orthogonal to the axis of the through-hole,
the second abutment surface faces a second surface different from the first surface of the three-dimensional wiring substrate,
the selective transmission member includes a glass substrate and a wiring pattern provided on the glass substrate,
the glass substrate abuts on the second abutment surface,
the light receiver is provided on a surface on a side opposite to a surface in contact with the second abutment surface of the selective transmission member, and
the wiring pattern abuts on the three-dimensional wiring substrate and the light receiver.

5. The optical device according to claim 4, wherein
the light receiver includes a protrusion provided on an electrode of the light receiver, and
the protrusion abuts on the wiring pattern.

6. The optical device according to claim 2, further comprising
a spacer provided inside the through-hole, wherein
the optical component includes at least a first optical component and a second optical component,
the first optical component abuts on the first abutment surface,
the second optical component abuts on the spacer, and
the spacer has a distal end located in a vicinity of the first optical component.

7. The optical device according to claim 1, wherein
the selective transmission member includes a diffraction grating that transmits a light at a wavelength in a predetermined range among lights incident on the selective transmission member.

8. The optical device according to claim 1, wherein
the light receiver or the selective transmission member includes a diffraction grating that causes the light receiver to receive light at a wavelength different depending on each pixel.

9. The optical device according to claim 1, wherein
the selective transmission member includes a plasmon filter that causes the light receiver to receive a light at a wavelength different depending on each pixel.

10. A spectral sensor module comprising:
the optical device according to claim 1, and
a diffuser as the optical component, wherein
the light receiver is a spectral sensor configured to measure intensity of the light that has transmitted through the selective transmission member for each wavelength.

11. An imaging module comprising:
the optical device according to claim 1; and
a lens unit that includes a plurality of lenses as the optical component, wherein
the light receiver is an imaging element.

12. A method for manufacturing an optical device comprising:
(a) placing a three-dimensional wiring substrate including a first abutment surface and a second abutment surface orthogonal to an axis of a through-hole opening to a first surface and a second surface with the second surface upward;
(b) inserting a selective transmission member that transmits a light at a predetermined wavelength into the through-hole and bringing the selective transmission member into abutment with the second abutment surface to provide the selective transmission member inside the through-hole;
(c) inserting a light receiver that receives the light that has transmitted through the selective transmission member into the through-hole;
(d) placing the three-dimensional wiring substrate with the first surface upward;
(e) inserting an optical component into the through-hole and bringing the optical component into abutment with the first abutment surface to provide the optical component inside the through-hole; and
(f) inserting an upper end member into the through-hole, bringing the upper end member into abutment with the optical component, and sealing an adhesive between the upper end member and the through-hole to provide the upper end member inside the through-hole.

13. The method for manufacturing the optical device according to claim 12, wherein
the optical component includes at least a first optical component and a second optical component, and
step (e) comprises:
(e1) inserting the first optical component into the through-hole and bringing the first optical component into abutment with the first abutment surface to provide the first optical component inside the through-hole;
(e2) inserting a spacer into the through-hole and bringing the spacer into abutment with the first optical component to provide the spacer inside the through-hole; and
(e3) inserting the second optical component into the through-hole and bringing the second optical component into abutment with the spacer to provide the second optical component inside the through-hole.

14. The method for manufacturing the optical device according to claim 12, wherein
the three-dimensional wiring substrate includes a third abutment surface orthogonal to the axis of the through-hole, and
in step (c), the light receiver is brought into abutment with the third abutment surface to electrically conduct the light receiver and the three-dimensional wiring substrate.

15. The method for manufacturing the optical device according to claim 12, wherein
the selective transmission member includes a wiring pattern formed on a surface of the selective transmission member,
in step (b), the wiring pattern is electrically conducted with the three-dimensional wiring substrate, and
in step (c), the light receiver is brought into abutment with the selective transmission member to electrically conduct the wiring pattern and the light receiver.
